(19) United States
(12) Patent Application Publication
(10) Pub. No.: US 2025/0223421 A1
(43) Pub. Date: Jul. 10, 2025

(54) CONDUCTIVE COMPOSITIONS FOR ADDITIVE MANUFACTURING, ADDITIVE MANUFACTURING METHODS, ELECTRICALLY CONDUCTIVE TRACES PRODUCED THEREFROM, AND ELECTRONIC ARTICLES

(71) Applicant: XTPL S.A., Wroclaw (PL)

(72) Inventors: Ludovic SCHNEIDER, Wroclaw (PL); Aleksandra MOTYKA, Skopanie (PL); Jolanta GADZALINSKA, Dzialoszyn (PL)

(73) Assignee: XTPL S.A., Wroclaw (PL)

(21) Appl. No.: 18/981,779

(22) Filed: Dec. 16, 2024

Related U.S. Application Data
(60) Provisional application No. 63/617,574, filed on Jan. 4, 2024.

(51) Int. Cl. C08K 3/105; B29C 64/118; B29K 105/16; B33Y 70/10

(52) U.S. Cl. CPC C08K 3/105; B33Y 70/10; B29C 64/118; B29K 2105/162; B29K 2995/0005; C08K 2201/001; C08K 2201/005; C08K 2201/011

(57) ABSTRACT

Conductive compositions for additive manufacturing, additive manufacturing methods, electrically conductive traces produced therefrom, and electronic articles are provided. The composition comprises at least 75 percent by weight of gold nanoparticles and at least 2 percent by weight of a polar solvent based, all based on the total weight of the composition. The gold nanoparticles comprise an average particle size of no greater than 100 nm as measured with transmission electron microscopy. The polar solvent has a boiling point of at least 200° C. The composition comprises less than 5 percent by weight of any solvent having a boiling point of less than 200° C. based on the total weight of the composition.

### CROSS-REFERENCE

This application claims priority to U.S. Provisional Patent Application No. 63/617,574, which was filed on Jan. 4, 2024. The contents of which is hereby incorporated by reference into this specification.

### BACKGROUND

Metallic nanoparticle compositions suitable for use in additive manufacturing processes, such as gold nanoparticle compositions, have been under development. There are challenges with gold nanoparticle compositions.

### SUMMARY

The present disclosure provides a conductive composition for additive manufacturing. The composition comprises at least 75 percent by weight of gold nanoparticles and at least 2 percent by weight of a polar solvent, all based on the total weight of the composition. The gold nanoparticles comprise an average particle size of no greater than 100 nm as measured with transmission electron microscopy. The polar solvent has a boiling point of at least 200° C. The composition comprises less than 5 percent by weight of any solvent having a boiling point of less than 200° C. based on the total weight of the composition.

The present disclosure provides a conductive composition for additive manufacturing. The composition comprises 80 percent to 90 percent by weight of gold nanoparticles, 2 percent to 19 percent by weight of a solvent comprising tetraethylene glycol, 1 percent to 3 percent by weight of a polymeric dispersant, and 1 percent to 3 percent by weight of a rheological agent, all based on the total weight of the composition. The gold nanoparticles comprise an average particle size in a range of 20 nm to 55 nm as measured with transmission electron microscopy. The gold nanoparticles comprise gold bound to a polymer having a molecular weight in a range of 24,000 daltons to 90,000 daltons. The composition comprises less than 5 percent by weight of any solvent having a boiling point of less than 200° C. based on the total weight of the composition.

The present disclosure also provides an additive manufacturing method. The method comprises extruding a conductive composition from a nozzle of an additive manufacturing system, thereby producing an electrically conductive feature. The composition comprises at least 75 percent by weight of gold nanoparticles and at least 2 percent by weight of a polar solvent, all based on the total weight of the composition. The gold nanoparticles comprise an average particle size of no greater than 100 nm as measured with transmission electron microscopy. The polar solvent has a boiling point of at least 200° C. The composition comprises less than 5 percent by weight of any solvent having a boiling point of less than 200° C. based on the total weight of the composition.

The present disclosure also provides an electrically conductive trace formed by sintering a conductive composition. The composition comprises at least 75 percent by weight of gold nanoparticles and at least 2 percent by weight of a polar solvent, all based on the total weight of the composition. The gold nanoparticles comprise an average particle size of no greater than 100 nm as measured with transmission electron microscopy. The polar solvent has a boiling point of at least 200° C. The composition comprises less than 5 percent by weight of any solvent having a boiling point of less than 200° C. based on the total weight of the composition.

The present disclosure also provides an electronic article comprising an electrically conductive trace. The electrically conductive trace is formed by sintering a conductive composition. The composition comprises at least 75 percent by weight of gold nanoparticles and at least 2 percent by weight of a polar solvent, all based on the total weight of the composition. The gold nanoparticles comprise an average particle size of no greater than 100 nm as measured with transmission electron microscopy. The polar solvent has a boiling point of at least 200° C. The composition comprises less than 5 percent by weight of any solvent having a boiling point of less than 200° C. based on the total weight of the composition.

The present disclosure provides conductive compositions for additive manufacturing, additive manufacturing methods, electrically conductive traces produced therefrom, and electronic articles therefrom that can provide enhanced electrical conductivity, printability, homogeneity, and/or form unique structures.

It is understood that the inventions described in this specification are not limited to the examples summarized in this Summary. Various other aspects are described and exemplified herein.

### BRIEF DESCRIPTION OF THE DRAWING

The features and advantages of the examples, and the manner of attaining them, will become more apparent, and the examples will be better understood, by reference to the following description taken in conjunction with the accompanying drawing, wherein:

FIG. 1 is a perspective view of an additive manufacturing system forming a conductive trace on a substrate of an electronic article;

FIG. 2A is an image of example conductive traces extruded using first parameters according to the present disclosure;

FIG. 2B is an image of example conductive traces extruded using second parameters according to the present disclosure;

FIG. 2C is an image of example conductive traces extruded using third parameters according to the present disclosure;

FIG. 2D is an image of example conductive traces extruded using fourth parameters according to the present disclosure;

FIG. 2E is an image of example conductive traces extruded using fifth parameters according to the present disclosure;

FIG. 2F is an image of example conductive traces extruded using sixth parameters according to the present disclosure;

FIG. 3A shows a top-view image of an example conductive trace captured using a transmission electron microscope; and

FIG. 3B shows a side-view image of the conductive trace of FIG. 3A captured using a transmission electron microscope.

The exemplifications set out herein illustrate certain embodiments, in one form, and such exemplifications are not to be construed as limiting the scope of the appended claims in any manner.

### DETAILED DESCRIPTION

Certain exemplary aspects of the present disclosure will now be described to provide an overall understanding of the principles of the structure, function, manufacture, and use of the compositions, methods, and products disclosed herein. One or more examples of these aspects are illustrated in the accompanying drawings. Those of ordinary skill in the art will understand that the devices and methods specifically described herein and illustrated in the accompanying drawings are non-limiting exemplary aspects and that the scope of the various examples of the present disclosure is defined solely by the claims. The features illustrated or described in connection with one exemplary aspect may be combined with the features of other aspects. Such modifications and variations are intended to be included within the scope of the present disclosure.

Any references herein to “various examples,” “some examples,” “one example,” “an example,” similar references to “aspects,” or the like, means that a particular feature, structure, or characteristic described in connection with the example is included in at least one example. Thus, appearances of the phrases “in various examples,” “in some examples,” “in one example,” “in an example,” similar references to “aspects,” or the like, in places throughout the specification are not necessarily all referring to the same example. Furthermore, the particular features, structures, or characteristics may be combined in any suitable manner in one or more examples. Thus, the particular features, structures, or characteristics illustrated or described in connection with one example may be combined, in whole or in part, with the features, structures, or characteristics of one or more other examples without limitation. Such modifications and variations are intended to be included within the scope of the present examples.

Metallic nanoparticle compositions suitable for additive manufacturing have been manufactured, such as those described in U.S. Pat. No. 11,549,026 and U.S. patent application Ser. No. 17/425,660, which are hereby incorporated by reference. The present disclosure provides conductive compositions for additive manufacturing, additive manufacturing methods, electrically conductive traces produced therefrom, and electronic articles therefrom that can provide enhanced electrical conductivity, printability, homogeneity, and/or form unique structures. For example, the conductive compositions can include higher concentrations of metallic nanoparticles that can enable enhanced conductivity in structures formed therefrom. As another example, the conductive compositions can enable enhanced conductivity in structures by forming higher aspect ratio structures after a single pass with a print head.

The conductive composition for additive manufacturing comprises gold nanoparticles, a polar solvent, and optionally additives, such as, for example, a second solvent, a dispersant and/or a rheological agent. The conductive composition can be formulated to provide the desired electrical conductivity, printability, and/or homogeneity. The conductive composition can be electrically conductive.

For example, the conductive composition comprises at least 75 percent by weight of gold nanoparticles based on the total weight of the composition, such as, for example, at least 76 percent by weight, at least 77 percent by weight, at least 78 percent by weight, at least 79 percent by weight, at least 80 percent by weight, at least 81 percent by weight, at least 82 percent by weight, at least 83 percent by weight, at least 85 percent by weight, or at least 90 percent by weight of gold nanoparticles based on the total weight of the composition. The conductive composition can comprise no greater than 98 percent by weight of gold nanoparticles based on the total weight of the composition, such as, for example, no greater than 95 percent by weight, no greater than 94 percent by weight, no greater than 93 percent by weight, no greater than 92 percent by weight, no greater than 91 percent by weight, no greater than 90 percent by weight, no greater than 89 percent by weight, or no greater than 85 percent by weight gold nanoparticles based on the total weight of the composition. The conductive composition can comprise a range of 75 percent to 98 percent gold nanoparticles, such as, for example, 76 percent to 95 percent, 80 percent to 95 percent, 85 percent to 95 percent, 90 percent to 95 percent, 81 percent to 90, or 80 percent to 95 percent by weight of gold nanoparticles based on the total weight of the composition. The high gold concentration can provide the desired electrical conductivity and/or homogeneity of a printed trace. The high gold concentration can enable shear-thinning of the conductive composition, thereby enabling enhanced printability through a nozzle of a print head.

The size and/or shape of the gold nanoparticles can be selected such that the conductive composition can be suitable for additive manufacturing and/or packing such that the gold nanoparticles can be sintered after additive manufacturing to form a conductive trace with an enhanced homogeneity. The gold nanoparticles comprise an average particle size of no greater than 100 nm as measured with transmission electron microscopy (TEM), such as, for example, no greater than 95 nm, no greater than 90 nm, no greater than 85 nm, no greater than 80 nm, no greater than 75 nm, no greater than 70 nm, no greater than 65 nm, no greater than 60 nm, no greater than 55 nm, no greater than 50 nm, no greater than 45 nm, or no greater than 40 nm, all as measured with TEM. The gold nanoparticles can comprise an average particle size of at least 1 nm, such as, for example, at least 5 nm, at least 10 nm, at least 15 nm, at least 20 nm, at least 25 nm at least 30 nm, at least 35 nm at least 40 nm, at least 45 nm, at least 50 nm, at least 60 nm, or at least 70 nm, all as measured with TEM. The gold nanoparticles can comprise an average particle size in a range of 1 nm to 300 nm, such as, for example, 5 nm to 100 nm, 10 nm to 80 nm, 10 nm to 70 nm, 5 nm to 70 nm, 5 nm to 60 nm, 5 nm to 55 nm, 5 nm to 50 nm, 10 nm to 70 nm, 10 nm to 60 nm, 10 nm to 50 nm, 20 nm to 70 nm, 20 nm to 60 nm, 20 nm to 55 nm, 20 nm to 50 nm, 50 nm to 100 nm, or 25 nm to 75 nm. A suitably reduced particle size can enhance printability, sinterability, and/or mechanical and electrical characteristics of an electrical trace formed the conductive composition, while enabling a higher gold nanoparticle concentration.

As used herein, “average particle size” refers to the mean average feret diameter of the particles.

The shape of the gold nanoparticles can be amorphous, spherical, triangular, rod-shaped, or a combination thereof. For example, the gold nanoparticles can comprise a mixture of amorphous nanoparticles, spherical nanoparticles, triangular nanoparticles, and/or rod-shaped nanoparticles. In some examples, the gold nanoparticles can comprise a mixture of 60% to 80% by weight of spherical nanoparticles, 15% to 25% by weight of triangular nanoparticles, and 5% to 15% by weight of rod-shaped nanoparticles, all based on the total weight of the gold nanoparticles. In some examples, the gold nanoparticles can comprise a mixture of 80% to 95% by weight of spherical nanoparticles and 5% to 20% by weight of nanoparticles that are not spherical nanoparticles.

As used herein, a “spherical nanoparticle” refers to a nanoparticle with a sphericity of no less than 0.9. For example, a spherical nanoparticle many not be perfectly spherical (e.g., may not have a sphericity of 1.0) and can include one or more than one surfaces having various shapes, such as, for example, a surface having a triangular shape, a surface having a trapezoidal shape, a surface having a pentagonal shape, and/or a surface having a hexagonal shape.

As used herein, a “rod-shaped nanoparticle” refers to a nanoparticle with a length-to-width aspect ratio (e.g., a length-to-diameter aspect ratio) of no less than 2:1, and that is not a spherical nanoparticle.

As used herein, a “triangular nanoparticle” refers to a nanoparticle with at least one triangular-shaped surface, and that is not a spherical nanoparticle or a rod-shaped nanoparticle.

As used herein, an “amorphous nanoparticle” refers to a nanoparticle that is not a spherical nanoparticle, a rod-shaped nanoparticle, or a triangular nanoparticle.

The gold nanoparticles can comprise gold (e.g., metallic gold) bound to a polymer. For example, the gold nanoparticles can comprise at least 90% metallic gold based on the total weight of the gold nanoparticles or at least 95% metallic gold based on the total weight of the gold nanoparticles. The polymer can enhance dispersibility of the gold nanoparticles, enhance stability of the gold nanoparticles, and/or reduce aggregation of the gold nanoparticles, thereby enhancing printability and/or homogeneity of a conductive trace formed therefrom. The polymer can serve as adhesion promoter for the conductive composition, for example, inhibiting cracking during drying of the conductive composition (e.g., during sintering) and/or inhibiting delamination of the conductive composition from a substrate.

The polymer can comprise a weight-average molecular weight in a range of 24,000 daltons to 90,000 daltons as measured according to ASTM D4001-20, such as, for example, 30,000 daltons to 60,000 daltons, or 35,000 daltons to 65,000 daltons. The molecular weight of the polymer can correlate to a length of the polymer and thus, the resulting size of the nanoparticles formed therefrom. Selecting a desirable molecular weight can enhance dispersibility and/or reduce aggregation of the gold nanoparticles.

The polymer can be a phosphoric acid derivative (e.g., a polymer with a phosphate group). For example, the polymer can comprise a polyetherketone, such as, for example, polyvinylpyrrolidone (PVP). In some examples, the polymer can comprise polyvinylpyrrolidone, poly(vinyl alcohol), poly(ethylene glycol), poly(methacrylic acid), polymethylmethacrylate, or a combination thereof. Selecting a polymer that is soluble in the polar solvent can enhance printability and/or homogeneity of the conductive composition. Balancing the particle size, particle shape, particle packing, polymer composition, polymer length, and solvent composition, can lead to an increased gold concentration in the conductive composition while maintaining printability of the conductive composition.

The conductive composition comprises at least 2 percent by weight of the polar solvent based on the total weight of the composition, such as, for example, at least 3 percent, at least 5 percent, at least 6 percent, at least 7 percent, at least 8 percent, at least 9 percent, at least 10 percent, at least 11 percent, or at least 12 percent by weight of the polar solvent based on the total weight of the composition. The conductive composition can comprise no greater than 25 percent by weight of the polar solvent based on the total weight of the composition, such as, for example, no greater than 24 percent by weight, no greater than 23 percent by weight, no greater than 22 percent by weight, no greater than 21 percent by weight, no greater than 20 percent by weight, no greater than 19 percent by weight, no greater than 17 percent by weight, or no greater than 15 percent by weight of the solvent based on the total weight of the composition. The composition can comprise a range of polar solvent of 2 percent to 25 percent by weight based on the total weight of the composition, such as, for example, 2 percent to 19 percent, 3 percent to 24 percent, 5 percent to 20 percent, 10 percent to 20 percent, 12 percent to 17 percent, or 12 percent to 15 percent by weight of the polar solvent based on the total weight of the composition.

The boiling point of the polar solvent can be selected to enhance the printability of the conductive composition such that minimal, if any, polar solvent evaporates while extruding at an elevated temperature and/or under an elevated pressure. Evaporation of the polar solvent while extruding the conductive composition via a nozzle can cause other components of the conductive composition to foul or otherwise obstruct the nozzle. The polar solvent can comprise a boiling point of at least 200° C., such as, for example, at least 210° C., at least 220° C., at least 230° C., at least 240° C., at least 245° C., at least 250° C., or at least 255° C. The polar solvent can comprise a boiling point of no greater than 600° C., such as, for example, no greater than 550° C., no greater than 400° C., no greater than 375° C., no greater than 350° C., or greater than 340° C., or greater than 280° C. The polar solvent can comprise a boiling point in a range of 200° C. to 600° C., such as, for example, 200° C. to 350° C., 220° C. to 350° C., 240° C. to 350° C., 240° C. to 340° C., 220° C. to 280° C., or 240° C. to 280° C. As used herein, a boiling point is measured at a pressure of 1 atmosphere absolute.

The polar solvent can comprise a polar protic solvent such that the polar solvent may participate in hydrogen bonding, which may stabilize the conductive composition, inhibit phase separation in the conductive composition, and/or reduce agglomeration of the gold nanoparticles. The polar solvent can comprise triethylene glycol, triethylene glycol methyl ether, glycerol, tripropylene glycol, tripropylene glycol methyl ether, diethylene glycol, tetraethylene glycol, or a combination thereof. For example, the polar solvent can be a mixture of tetra ethylene glycol and diethylene glycol. The polar solvent can consist essentially of tetraethylene glycol.

The conductive composition can comprise optional additives for further adjustment of physiochemical properties. For example, the optional additives can comprise an additional solvent, a surfactant, a binder, an adhesion promoter, an antifoaming agent, a wetting agent, an antioxidant (e.g., citric acid), or a combination thereof.

In some examples, the conductive composition can comprise a solvent in addition to the polar solvent (e.g., a second solvent). In some examples, the conductive composition may not include any solvents in addition to the polar solvent. The weight percentage and/or the boiling point of any solvents included in the conductive composition can be selected to enhance the printability of the conductive composition by minimizing the amount of solvent, if any, that evaporates while extruding at an elevated temperature and/or under an elevated pressure. Evaporation of solvents while extruding the conductive composition via a nozzle can cause other components of the conductive composition to foul or otherwise obstruct the nozzle. The composition can comprise less than 5 percent by weight of any solvent having a boiling point of less than 200° C. based on the total weight of the composition, such as, for example, less than 4 percent by weight of any solvent having a boiling point of less than 200° C., less than 3 percent by weight of any solvent having a boiling point of less than 200° C., less than 2 percent by weight of any solvent having a boiling point of less than 200° C., less than 1 percent by weight of any solvent having a boiling point of less than 200° C., less than 5 percent by weight of any solvent having a boiling point of less than 220° C., less than 4 percent by weight of any solvent having a boiling point of less than 220° C., less than 3 percent by weight of any solvent having a boiling point of less than 220° C., less than 2 percent by weight of any solvent having a boiling point of less than 220° C., or less than 1 percent by weight of any solvent having a boiling point of less than 220° C.

The conductive composition can include a dispersant. The dispersant can enhance the stability of the conductive composition, inhibit phase separation, and/or reduce agglomeration of the gold nanoparticles. The conductive composition can comprise at least 0.1 percent by weight of the dispersant based on the total weight of the composition, such as, for example, at least 0.5 percent, at least 0.75 percent, or at least 1 percent by weight based on the total weight of the composition. The conductive composition can comprise no greater than 3 percent by weight of the polymer dispersant, such as, for example, no greater than 2.5 percent, no greater than 2 percent, or no greater than 1.5 percent by weight of the polymeric dispersant. The conductive composition can comprise 0.1 percent to 3 percent by weight of the polymeric dispersant, such as, for example, 0.1 percent to 2 percent by weight or 1 percent to 3 percent by weight of the polymeric dispersant based on the total weight of the composition.

The dispersant can be polymeric. For example, the dispersant can comprise an alkylol ammonium salt of a copolymer with acidic groups, a phosphoric acid derivative, or a combination thereof.

The conductive composition can comprise no greater than 10 percent by weight of additives based on the total weight of the composition, such as, for example, no greater than 5 percent, no greater than 4 percent, no greater than 3 percent, no greater than 2 percent, or no greater than 1 percent by weight of additives. The conductive composition can comprise greater than 0 to 0.5 percent by weight citric acid or 0.05 to 0.5 percent by weight citric acid.

The conductive composition can comprise an adhesion promoter, for example, in addition to adhesion promotion that may be provided by a polymer bound to the gold in the gold nanoparticles. The adhesion promoter can inhibit cracking during drying of the conductive composition (e.g., during sintering) and/or inhibit delamination of the conductive composition from a substrate. The conductive composition can comprise at least 0.5 percent by weight of the adhesion promoter based on the total weight of the conductive composition, such as, for example, at least 0.6 percent, at least 0.7 percent, at least 0.8 percent, at least 0.9 percent, at least 1 percent, or at least 1.5 percent, all based on the total weight of the conductive composition. The conductive composition can comprise no greater than 2 percent by weight of an adhesion promoter based on the total weight of the conductive composition, such as, for example, no greater than 1.75 percent by weight of an adhesion promoter or no greater than 1.5 percent by weight of an adhesion promoter, all based on the total weight of the conductive composition. The conductive composition can comprise a concentration of the adhesion promoter in a range of 0.5 percent to 2.0 percent by weight based on the total weight of the conductive composition, such as, for example, 0.6 percent to 1.5 percent by weight based on the total weight of the conductive composition. Having too little adhesion promoter may not produce a desired adhesive effect. Having too much adhesion promoter may decrease printability, undesirably affect the viscosity of the conductive composition, and/or hinder electrical properties of the conductive composition.

The adhesion promoter can comprise a polymer, such as, for example, a polyetherketone (e.g., PVP). The adhesion promoter can comprise an alkyl ammonium salt, a hydroxy-functional copolymer with an acidic group, a phenol, an epoxide, or a combination thereof.

The adhesion promoter can comprise a molecular weight greater than a molecular weight of a polymer bound to gold in the gold nanoparticles. For example, the adhesion promoter can comprise a molecular weight of at least 500,000 daltons as measured according to ASTM D4001-20, such as, for example, at least 1,000,000 daltons, at least 2,000,000 daltons, or at least 3,000,000 daltons, all as measured according to ASTM D4001-20.

The components of the conductive composition can be selected such that a desirable viscosity of the conductive composition is achieved. The viscosity can affect the printability of the conductive composition and/or the ability of the conductive composition to hold a desired shape after extrusion and prior to sintering during additive manufacturing. The conductive composition can comprise a dynamic viscosity of at least 100 cP as measured at 25 degrees Celsius with a rheometer with a 25 mm parallel plate measuring system and a shear rate in a range of 0.1 s⁻¹ to 100 s⁻¹, such as, for example, at least 10,000 cP, at least 100,000 cP, at least 120,000 cP, at least 200,000 cP, at least 300,000 cP, at least 400,000 cP, at least 500,000 cP, at least 1,000,000 cP, at least 10,000,000 cP, or at least 20,000,000 cP, all as measured at 25 degrees Celsius with a rheometer with a 25 mm parallel plate measuring system and a shear rate in a range of 0.1 s⁻¹ to 100 s⁻¹. The conductive composition can comprise a dynamic viscosity of no greater than 100,000,000 cP as measured at 25 degrees Celsius with a rheometer with a 25 mm parallel plate measuring system and a shear rate in a range of 0.1 s⁻¹ to 100 s⁻¹, such as, for example, no greater than 10,000,000 cP, no greater than 1,000,000 cP, no greater than 500,000 cP, no greater than 400,000 cP, or no greater than 300,000 cP, all as measured at 25 degrees Celsius with a rheometer with a 25 mm parallel plate measuring system and a shear rate in a range of 0.1 s⁻¹ to 100 s⁻¹. The conductive composition can comprise a dynamic viscosity in a range of 100 cP to 100,000,000 cP as measured at 25 degrees Celsius with a rheometer with a 25 mm parallel plate measuring system and a shear rate in a range of 0.1 s⁻¹ to 100 s⁻¹, such as, for example, 100,000 cP to 100,000,000 cP, 100,000 cP to 20,000,000 cP, 100,000 cP to 10,000,000 cP, 120,000 cP to 10,000,000 cP, or 200,000 to 10,000,000 cP, all as measured at 25 degrees Celsius with a rheometer with a 25 mm parallel plate measuring system and a shear rate in a range of 0.1 s⁻¹ to 100.

The conductive composition can reduce in viscosity responsive to a shear force. For example, the conductive composition can be a pseudoplastic fluid. The increased concentration of the gold nanoparticles can cause create non-newtonian behavior of the conductive composition that can enable a shear-thinning phenomena. The shear-thinning phenomena can enable efficient extrusion of the conductive composition through a nozzle of an additive manufacturing system.

The conductive composition can comprise a rheological agent. The rheological agent can be included in the conductive composition to achieve a desired viscosity. The conductive composition can comprise at least 0.1 percent by weight of the rheological agent based on the total weight of the conductive composition, such as, for example, at least 0.2 percent, at least 0.3 percent, at least 0.4 percent, at least 0.5 percent, at least 0.6 percent, at least 0.7 percent, at least 0.8 percent, at least 0.9 percent, at least 1 percent, at least 1.5 percent, at least 2 percent, at least 2.5 percent, or at least 3 percent, all based on the total weight of the conductive composition. The conductive composition can comprise no greater than 5 percent by weight of a rheological agent based on the total weight of the conductive composition, such as, for example, no greater than 4 percent by weight of a rheological agent, no greater than 3 percent by weight of a rheological agent, no greater than 2 percent by weight of a rheological agent, or no greater than 1 percent by weight of a rheological agent, all based on the total weight of the conductive composition. The conductive composition can comprise a concentration of a rheological agent in a range of 0.1 percent to 5.0 percent by weight based on the total weight of the conductive composition, such as, for example, 0.5 percent to 4 percent by weight, 0.5 percent to 3 percent by weight, or 1 percent to 3 percent by weight, all based on the total weight of the conductive composition. The viscosity of the conductive composition can be selected based on a line speed (e.g., a lateral movement velocity of a nozzle of an additive manufacturing system) to be used to print a line of the conductive composition onto a substrate. For example, a lower viscosity can enable more precise printing of a line of the conductive composition onto a substrate when printing at higher line speeds.

The rheological agent can comprise a polymer, such as, for example, an ethylene oxide-based urethane, an alkali-swellable emulsion polymer, a polyamide, polyvinyl pyrrolidone, or a combination thereof. The rheological agent may be hydrophobically modified.

The conductive composition can be manufactured by various methods, such as, for example, a poylol method. For example, a metal precursor (e.g., a gold salt such as HAuCl₄) can be combined with a solvent to form a first solution. The polymer can be combined with a solvent to form a second solution. The first solution and the second solution can be combined at a desirable temperature under agitation until the gold nanoparticles are formed. Reaction temperature, temperature heating/cooling rate, reaction time, a ratio of metal precursor to polymer, and/or solvent concentration can be selected to achieve a desirable size and/or shape of the gold nanoparticles. The gold nanoparticles can be separated from the remainder of the reaction medium to remove impurities and excess reagents. The gold nanoparticles can be concentrated in a rotary evaporator. The gold nanoparticles can be dispersed in the polar solvent optionally combined with additional additives.

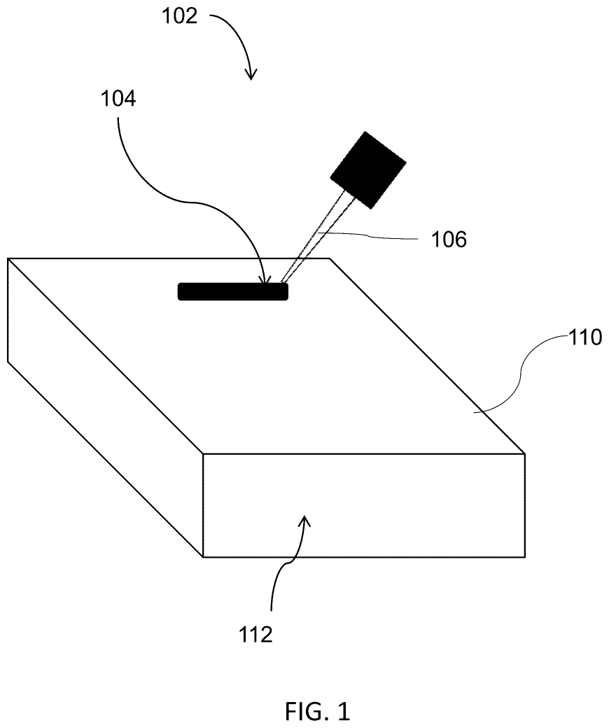

An electrically conductive feature can be formed from the conductive composition according to the present disclosure. Referring to FIG. 1, to form the electrically conductive feature 104, the conductive composition can be extruded from a nozzle 106 of an additive manufacturing system 102 and applied over a substrate 110 of an electronic article 112. As used herein, the terms “on,” “applied over,” “applied on,” “formed over,” “formed on, “deposited over,” “deposited on,” “overlay,” “provided over,” “provided on,” and the like, mean formed, overlaid, deposited, or provided on but not necessarily in contact with the surface. For example, a formed feature “applied over” a substrate does not preclude the presence of one or more other layers of the same or different composition located between the formed feature and the substrate.

The additive manufacturing system 102 can be configured to perform the methods as described herein and can comprise various hardware components in addition to the nozzle 106 to perform the methods as described herein. For example, the additive manufacturing system 102 can additionally comprise a print head, a substrate stage, a conductive composition feeding system, a print head positioning system (e.g., gantry), and a hardware controller. The electrically conductive feature may be formed by the additive manufacturing system in single continuous movement, multiple movements, a single layer, or multiple layers.

The nozzle 106 may move and deposit the conductive composition according to machine path instructions stored in memory of the additive manufacturing system 102 and/or of memory of a device in signal communication with the additive manufacturing system 102. The nozzle 106 can comprise an internal diameter in a range of 0.1 μm to 30 μm, such as, for example, 5 μm to 30 μm, 5 μm to 20 μm, or 8 μm to 20 μm. The nozzle may be moved at least in a lateral direction at a line speed in a range of 0.1 mm/s to 5 mm/s, such as, for example a line speed in a range of 0.1 mm/s to 2 mm/s, a line speed in a range of 0.1 mm/s to 2 mm/s, a line speed in a range of 0.1 mm/s to 0.5 mm/s, a line speed of 0.1 mm/s, a line speed of 0.2 mm/s, a line speed of 0.3 mm/s, a line speed of 0.4 mm/s, a line speed of 0.5 mm/s, a line speed of 0.6 mm/s, a line speed of 0.7 mm/s, a line speed of 0.8 mm/s, a line speed of 0.9 mm/s, a line speed of 1.0 mm/s, a line speed of 1.1 mm/s, a line speed of 1.2 mm/s, a line speed of 1.3 mm/s, a line speed of 1.4 mm/s, or a line speed of 1.5 mm/s.

The substrate 110 can be a printed circuit board (PCB) or other electronic hardware component. For example, the substrate 110 can be at least partially coated with silicon and have various electronic components (e.g., pads, vias, resistors, capacitors, LEDs). The electronic article 112 can be an electrical circuit, a thin conductive film, a display, or other electronic article.

The electrically conductive feature 104 can be formed in various shapes and sizes. For example, the electrically conductive feature 104 can comprise a line width of no greater than 100 μm, such as, for example, no greater than 10 μm. The electrically conductive feature 104 can comprise a line width in a range of 1 μm to 100 μm, such as, for example, 5 μm to 75 μm, 5 μm to 50 μm, 10 μm to 50 μm, 10 μm to 40 μm, 5 μm to 20 μm, 5 μm to 15 μm, 1 μm to 20 μm, or 1 μm to 10 μm.

The electrically conductive feature 104 can comprise an aspect ratio of at least 0.01, such as, for example, at least 0.02, at least 0.03, at least 0.04, at least 0.05, or at least 0.06. The electrically conductive feature 104 can comprise an aspect ratio in a range of 0.01 to 0.1, such as, for example, 0.01 to 0.06, 0.02 to 0.06, or 0.025 to 0.055. As used herein, an “aspect ratio” is a ratio of the height to the width of a structure (e.g., feature, trace). The height is measured from a base of the structure to a highest point of the structure. The width is measured at the base of the structure. The aspect ratio can be measured from a cross-section of the structure. Obtaining an desirable aspect ratio can enhance the electrical conductivity of a structure and/or enhance the mechanical stability of a structure.

After dispensing the conductive composition onto the substrate 110 to form the electrically conductive feature 104, the electrically conductive feature 104 can be sintered to form an electrically conductive trace therefrom. For example, the electrically conductive feature 104 can be sintered in an oven at a temperature in a range of 220° C. to 500° C. for a time period of in a range of 5 minutes to 90 minutes, such as, for example, a temperature of in a range of 220° C. to 350° C. for a time period of in a range of 5 minutes to 15 minutes. The electrically conductive feature 104 can be sintered by photonic sintering, such as by using a laser or a flash lamp. The sintering process can remove the polymer from the gold nanoparticles and/or other organic components, thereby enhancing the conductivity of the electrically conductive trace and curing the electrically conductive trace. Optionally, the electrically conductive feature 104 can be pre-processed in an oven set at a temperature in a range of 100° C. to 300° C. for a time period in a range of 5 minutes to 60 minutes prior to sintering.

### Examples

The present disclosure will be more fully understood by reference to the following examples, which provide illustrative non-limiting aspects of the invention. It is understood that the invention described in this specification is not necessarily limited to the examples described in this section.

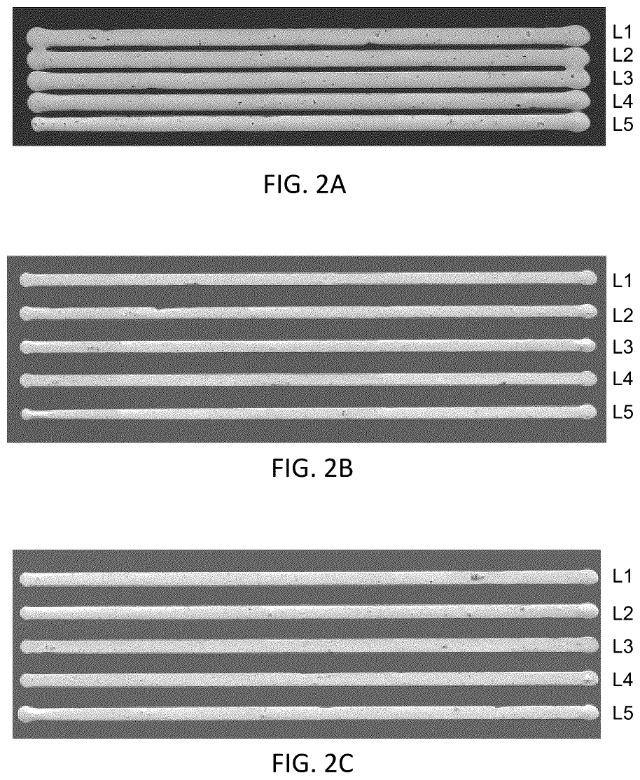

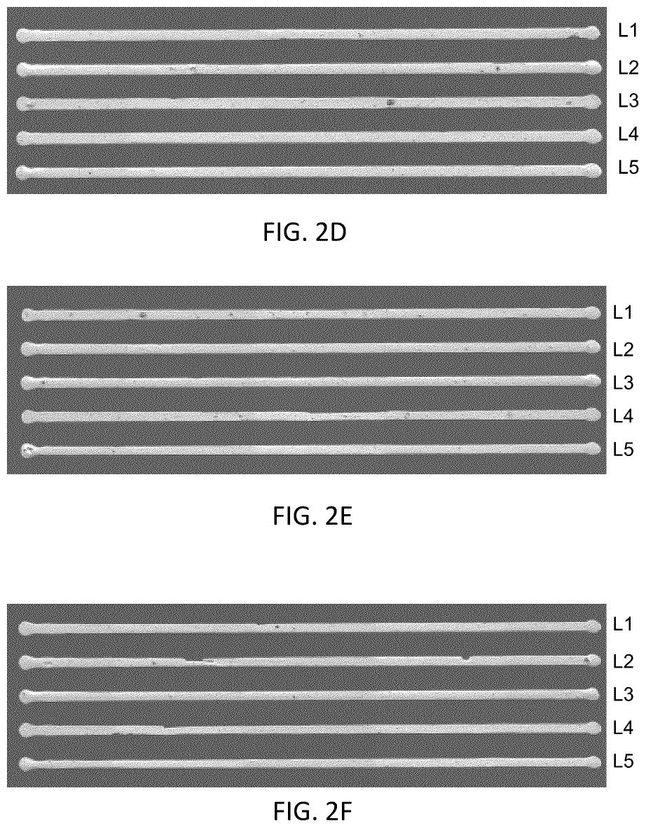

A first example conductive composition was manufactured according to the present disclosure. The first example conductive composition comprised gold nanoparticles with different shapes (e.g., spheres, rods) and an average particle size of 46 nm and a polyol solvent. Six (6) different combinations of printing parameters, combinations A-F, were chosen, as summarized in Table 1 below. Five (5) lines, lines L1-L5, of the conductive composition were extruded onto a substrate using a nozzle having a 10 μm diameter opening according to the parameters defined by each of the combinations A-F (e.g., resulting in 30 total lines). FIGS. 2A-2F respectively show top-view images captured of the resulting lines L1-L5 for each of the combinations A-F. Tables 2-7 below respectively summarizes the line widths and line heights of the lines L1-L5 for each of the combinations A-F.

TABLE 1
Example 1 - Printing Parameters

| | Printing | |
|---|---|---|
| Combination | Pressure | Line Speed |
| A | 1000 mbar | 0.1 mm/s |
| B | 700 mbar | 0.1 mm/s |
| C | 700 mbar | 0.2 mm/s |
| D | 700 mbar | 0.3 mm/s |
| E | 700 mbar | 0.4 mm/s |
| F | 700 mbar | 0.5 mm/s |

TABLE 2
Combination A

| Line | Width | Height |
|---|---|---|
| L1 | 14.03 μm | 779 nm |
| L2 | 13.77 μm | 756 nm |
| L3 | 14.03 μm | 767 nm |
| L4 | 13.24 μm | 753 nm |
| L5 | 12.97 μm | 692 nm |

TABLE 3
Combination B

| Line | Width | Height |
|---|---|---|
| L1 | 11.65 μm | 342 nm |
| L2 | 11.65 μm | 336 nm |
| L3 | 11.65 μm | 341 nm |
| L4 | 11.65 μm | 352 nm |
| L5 | 11.91 μm | 395 nm |

TABLE 4
Combination C

| Line | Width | Height |
|---|---|---|
| L1 | 9.79 μm | 263 nm |
| L2 | 9.79 μm | 267 nm |
| L3 | 10.32 μm | 262 nm |
| L4 | 10.32 μm | 263 nm |
| L5 | 9.79 μm | 302 nm |

TABLE 5
Combination D

| Line | Width | Height |
|---|---|---|
| L1 | 8.21 μm | 227 nm |
| L2 | 8.74 μm | 240 nm |
| L3 | 8.47 μm | 245 nm |
| L4 | 9.00 μm | 232 nm |
| L5 | 9.27 μm | 256 nm |

TABLE 6
Combination E

| Line | Width | Height |
|---|---|---|
| L1 | 7.94 μm | 220 nm |
| L2 | 7.94 μm | 217 nm |
| L3 | 7.68 μm | 227 nm |
| L4 | 7.15 μm | 223 nm |
| L5 | 7.41 μm | 240 nm |

TABLE 7
Combination F

| Line | Width | Height |
|---|---|---|
| L1 | 7.68 μm | 207 nm |
| L2 | 7.94 μm | 176 nm |
| L3 | 7.68 μm | 204 nm |
| L4 | 7.41 μm | 221 nm |
| L5 | 7.41 μm | 246 nm |

A second example conductive composition was manufactured according to the present disclosure. The second example conductive composition comprised gold nanoparticles with different shapes (e.g., spheres, rods) and an average particle size of 46 nm, and a polyol solvent. Five (5) different combinations of printing and sintering parameters, combinations G-K, were chosen, as summarized in Table 8 below. The tip of a nozzle having a 10 μm diameter opening was broken off to create an opening having a diameter in a range of 15 μm and 20 μm and used for the printing. Varying numbers of lines (e.g., L1, L2, L3, . . . . Ln) of the conductive composition were extruded onto a substrate and then sintered according to the parameters defined by each of the combinations G-K. Tables 9-13 below respectively summarizes the line widths, line heights, resistance, calculated bulk percentage based on an assumed semicircular cross section of the line using the line height and width, and calculated bulk percentage based a measured line cross-sectional area for each of the lines in combinations G-K.

TABLE 8
Example 2 - Sintering Parameters

| | Printing | | Sintering | Sintering |
|---|---|---|---|---|
| Combination | Pressure | Line Speed | Temperature | Duration |
| G | 500 mbar | 0.5 mm/s | 250 | 5 |
| H | 500 mbar | 0.5 mm/s | 250 | 10 |
| I | 500 mbar | 0.5 mm/s | 250 | 15 |
| J | 500 mbar | 0.5 mm/s | 300 | 5 |
| K | 700 mbar | 0.5 mm/s | 300 | 10 |

TABLE 9
Combination G

| | | | | | Bulk | |
|---|---|---|---|---|---|---|
| | | | | | Percentage | Bulk |
| | | | | | (assumed | Percentage |
| | | | | Resis- | semicircular | (line cross |
| Line | Width | Height | Length | tance | shape) | section) |
| L1 | 21.18 μm | 710 nm | 888 mm | 24.9 Ω | 6.87% | 7.42% |
| L2 | 10.06 μm | 300 nm | 892 mm | 131.3 Ω | 6.52% | 6.11% |
| L3 | 7.68 μm | 367 nm | 859 mm | 134.5 Ω | 6.56% | 6.59% |
| L4 | 7.15 μm | 320 nm | 836 mm | 149.9 Ω | 7.06% | 6.47% |

TABLE 10
Combination H

| | | | | | Bulk | |
|---|---|---|---|---|---|---|
| | | | | | Percentage | Bulk |
| | | | | | (assumed | Percentage |
| | | | | Resis- | semicircular | (line cross |
| Line | Width | Height | Length | tance | shape) | section) |
| L1 | 7.15 μm | 350 nm | 820 mm | 109.0 Ω | 8.70% | 8.71% |
| L2 | 7.68 μm | 338 nm | 863 mm | 108.9 Ω | 8.84% | 9.45% |
| L3 | 7.15 μm | 340 nm | 822 mm | 129.9 Ω | 7.54% | 7.54% |
| L4 | 7.41 μm | 320 nm | 894 mm | 106.5 Ω | 10.25% | 10.06% |
| L5 | 7.41 μm | 380 nm | 892 nm | 106.9 Ω | 8.58% | 9.26% |
| L6 | 6.88 μm | 310 nm | 907 nm | 109.6 Ω | 11.23% | 10.29% |
| L7 | 7.15 μm | 340 nm | 864 nm | 117.3 Ω | 8.77% | 9.24% |

TABLE 11
Combination I

| | | | | | Bulk | |
|---|---|---|---|---|---|---|
| | | | | | Percentage | Bulk |
| | | | | | (assumed | Percentage |
| | | | | Resis- | semicircular | (line cross |
| Line | Width | Height | Length | tance | shape) | section) |
| L1 | 7.68 μm | 310 nm | 840 mm | 47.3 Ω | 21.6% | 20.79% |
| L2 | 7.41 μm | 320 nm | 853 mm | 52.2 Ω | 19.95% | 18.58% |
| L3 | 7.41 μm | 302 nm | 844 mm | 52.9 Ω | 20.64% | 20.74% |
| L4 | 7.41 μm | 300 nm | 844 mm | 51.8 Ω | 21.22% | 19.89% |
| L5 | 7.68 μm | 310 nm | 890 nm | 60.8 Ω | 17.80% | 19.42% |

TABLE 12
Combination J

| | | | | | Bulk | |
|---|---|---|---|---|---|---|
| | | | | | Percentage | Bulk |
| | | | | | (assumed | Percentage |
| | | | | Resis- | semicircular | (line cross |
| Line | Width | Height | Length | tance | shape) | section) |
| L1 | 7.15 μm | 260 nm | 875 mm | 34.02 Ω | 37.34% | 35.64% |
| L2 | 7.15 μm | 270 nm | 845 mm | 35.03 Ω | 36.18% | 32.89% |
| L3 | 7.15 μm | 250 nm | 886 mm | 37.10 Ω | 38.68% | 35.43% |

TABLE 13
Combination K

| | | | | | Bulk | |
|---|---|---|---|---|---|---|
| | | | | | Percentage | Bulk |
| | | | | | (assumed | Percentage |
| | | | | Resis- | semicircular | (line cross |
| Line | Width | Height | Length | tance | shape) | section) |
| L1 | 9.53 μm | 433 nm | 879 mm | 16.2 Ω | 38.07% | 40.23% |
| L3 | 9.27 μm | 604 nm | 866 mm | 15.7 Ω | 28.52% | 27.35% |

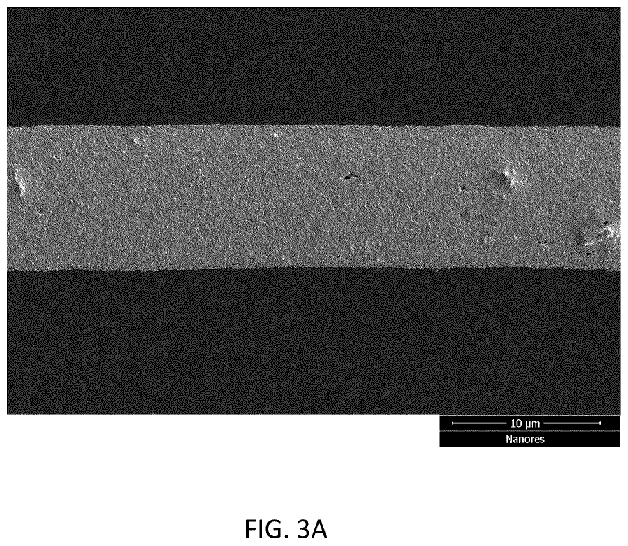

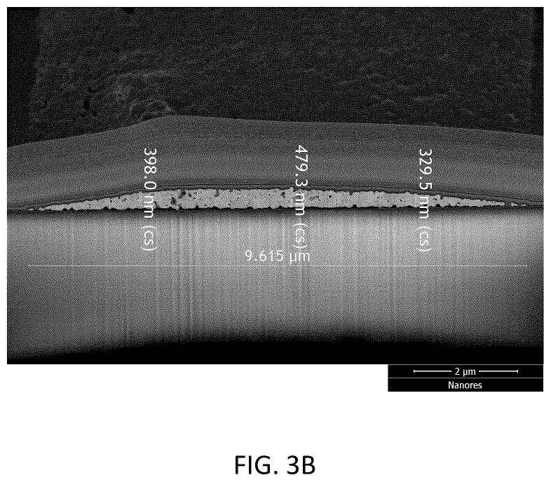

A third example of a conductive composition was manufactured according to the present disclosure. The second example conductive composition comprised gold nanoparticles with different shapes (e.g., spheres, rods) and an average particle size of 51 nm, and a polyol solvent. The conductive composition was extruded from a nozzle form a conductive trace. FIG. 3A shows a top-view image of the conductive trace and FIG. 3B shows side view image of the conductive trace.

As used herein, the terms “cure” and “curing” refer to the chemical crosslinking of components in an ink applied as a layer over a substrate and/or the physical drying of an ink through solvent or carrier evaporation.

Various aspects of the invention include, but are not limited to, the aspects listed in the following numbered clauses.

Clause 1. A conductive composition for additive manufacturing, the composition comprising: at least 75 percent by weight of gold nanoparticles based on a total weight of the composition, the gold nanoparticles comprise an average particle size of no greater than 100 nm as measured with transmission electron microscopy; and at least 2 percent by weight of a polar solvent based on the total weight of the composition, the polar solvent having a boiling point of at least 200° C., wherein the composition comprises less than 5 percent by weight of any solvent having a boiling point of less than 200° C. based on the total weight of the composition.

Clause 2. The composition of Clause 1, wherein the composition comprises less than 1 percent by weight of any solvent having a boiling point of less than 200° C. based on the total weight of the composition.

Clause 3. The composition of clause 1, wherein the composition comprises less than 0.1 percent by weight of any solvent having a boiling point of less than 200° C. based on the total weight of the composition.

Clause 4. The composition of any of clauses 1-3, wherein nanoparticles comprise gold bound to a polymer.

Clause 5. The composition of clause 4, wherein the polymer comprises a weight-average molecular weight in a range of 24,000 daltons to 90,000 daltons as measured according to ASTM D4001-20.

Clause 6. The composition of any of clauses 4-5, wherein the polymer comprises a polyetherketone.

Clause 7. The composition of any of clause 4-6, wherein the polymer comprises polyvinylpyrrolidone, poly(vinyl alcohol), poly(ethylene glycol), poly(methacrylic acid), polymethylmethacrylate, or a combination thereof.

Clause 8. The composition of any of clauses 1-7, wherein the gold nanoparticles comprise an average particle size in a range of 5 nm to 80 nm as measured by transmission electron microscopy.

Clause 9. The composition of any of clauses 1-8, wherein the gold nanoparticles comprise an average particle size in a range of 20 nm to 55 nm as measured by transmission electron microscopy.

Clause 10. The composition of any of clauses 1-9, wherein the gold nanoparticles comprise a mixture of spherical nanoparticles, rod-shaped nanoparticles, and triangular nanoparticles.

Clause 11. The composition of any of clauses 1-10, wherein the gold nanoparticles comprise 60 percent to 80 percent by weight of spherical nanoparticles, 10 percent to 20 percent by weight of triangular nanoparticles, and 0 percent to 5 percent by weight of rod-shaped nanoparticles, all based on the total weight of the gold nanoparticles.

Clause 12. The composition of any of clauses 1-11, wherein the gold nanoparticles comprise 80 percent to 95 percent by weight of spherical nanoparticles and 5 percent to 20 percent by weight of nanoparticles that are not spherical nanoparticles, all based on the total weight of the gold nanoparticles.

Clause 13. The composition of any of clauses 1-12, wherein the composition comprises 76 percent to 95 percent by weight of the gold nanoparticles based on the total weight of the composition.

Clause 14. The composition of any of clauses 1-13, wherein the composition comprises 80 percent to 95 percent by weight of the gold nanoparticles based on the total weight of the composition.

Clause 15. The composition of any of clauses 1-14, wherein the composition comprises 81 percent to 90 percent by weight of the gold nanoparticles based on the total weight of the composition.

Clause 16. The composition of any of clauses 1-11, wherein the gold nanoparticles comprise at least 90 percent gold based on the total weight of the gold nanoparticles.

Clause 17. The composition of any of clauses 1-16, wherein the polar solvent comprises a polar protic solvent.

Clause 18. The composition of any of clauses 1-17, wherein the polar solvent comprises triethylene glycol, glycerol, tripropylene glycol, tripropylene glycol methyl ether, diethylene glycol, tetraethylene glycol, or a combination thereof.

Clause 19. The composition of any of clauses 1-18, wherein the polar solvent comprises tetraethylene glycol.

Clause 20. The composition of any of clauses 1-19, further comprising a second solvent.

Clause 21. The composition of any of clauses 1-20, wherein the composition comprises 10 percent to 20 percent by weight of the polar solvent based on the total weight of the composition.

Clause 22. The composition of any of clauses 1-21, wherein the composition comprises 12 percent to 17 percent by weight of the polar solvent based on the total weight of the composition.

Clause 23. The composition of any of clauses 1-22, wherein the composition further comprises at least 0.1 weight percent of a dispersant based on the total weight of the composition.

Clause 24. The composition of clause 23, wherein the dispersant comprises an alkylol ammonium salt of a copolymer with acidic groups, a phosphoric acid derivative, or a combination thereof.

Clause 25. The composition of any of clauses 23-24, wherein the composition comprises 0.1 percent to 3 percent by weight of the dispersant based on the total weight of the composition.

Clause 26. The composition of any of clauses 23-25, wherein the composition comprises 1 percent to 3 percent by weight of the dispersant based on the total weight of the composition.

Clause 27. The composition of any of clauses 1-26, wherein the composition further comprises at least 0.1 weight percent of a rheological agent based on the total weight of the composition.

Clause 28. The composition of clause 27, wherein the composition comprises 1 percent to 3 percent by weight of the rheological agent based on the total weight of the composition.

Clause 29. The composition of any of clauses 27-28, wherein the rheological agent comprises an ethylene oxide-based urethane, an alkali-swellable emulsion, a polyamide, polyvinyl pyrrolidone, or a combination thereof.

Clause 30. The composition of any of clauses 1-29, wherein the composition comprises a dynamic viscosity of at least 100 cP as measured at 25 degrees Celsius with a rheometer with a 25 mm parallel plate measuring system and a shear rate in a range of 0.1 s⁻¹ to 100 s⁻¹.

Clause 31. The composition of any of clauses 1-30, wherein the composition reduces in viscosity responsive to a shear force.

Clause 32. A conductive composition for additive manufacturing, the composition comprising: 80 percent to 95 percent by weight of gold nanoparticles based on a total weight of the composition, the gold nanoparticles comprise an average particle size in a range of 20 nm to 55 nm as measured with transmission electron microscopy, wherein the gold nanoparticles comprise gold bound to a polymer having a molecular weight in a range of 24,000 daltons to 90,000 daltons; 2 percent to 19 percent by weight of a solvent comprising tetraethylene glycol; 1 percent to 3 percent by weight of a polymeric dispersant based on the total weight of the composition; and 1 percent to 3 percent by weight of a rheological agent based on the total weight of the composition, wherein the composition comprises less than 1 percent by weight of any solvent having a boiling point of less than 200° C. based on the total weight of the composition.

Clause 33. An additive manufacturing method, the method comprising extruding the composition of any of clauses 1-32 from a nozzle of an additive manufacturing system, thereby producing an electrically conductive feature.

Clause 34. The method of clause 33, wherein the electrically conductive feature comprises a line width of no greater than 10 μm.

Clause 35. The method of any of clauses 33-34, wherein the electrically conductive feature comprises an aspect ratio of at least 0.2.

Clause 36. The method of any of clauses 33-35, wherein extruding the composition of claim 1 from the nozzle of the additive manufacturing system is performed at a line speed 0.1 mm/s to 2 mm/s.

Clause 37. The method of any of clauses 33-36, further comprising sintering the electrically conductive feature, thereby forming an electrically conductive trace.

Clause 38. An electrically conductive trace formed by sintering the composition of any of clauses 1-32.

Clause 39. An electronic article comprising the electrically conductive trace of clause 38.

In this specification, unless otherwise indicated, all numerical parameters are to be understood as being prefaced and modified in all instances by the term “about”, in which the numerical parameters possess the inherent variability characteristic of the underlying measurement techniques used to determine the numerical value of the parameter. At the very least, and not as an attempt to limit the application of the doctrine of equivalents to the scope of the claims, each numerical parameter described herein should at least be construed in light of the number of reported significant digits and by applying ordinary rounding techniques.

Also, any numerical range recited herein includes all sub-ranges subsumed within the recited range. For example, a range of “1 to 10” includes all sub-ranges between (and including) the recited minimum value of 1 and the recited maximum value of 10, that is, having a minimum value equal to or greater than 1 and a maximum value equal to or less than 10. Any maximum numerical limitation recited in this specification is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited.

The grammatical articles “a,” “an,” and “the,” as used herein, are intended to include “at least one” or “one or more,” unless otherwise indicated, even if “at least one” or “one or more” is expressly used in certain instances. Thus, the articles are used herein to refer to one or more than one (i.e., to “at least one”) of the grammatical objects of the article. Further, the use of a singular noun includes the plural, and the use of a plural noun includes the singular, unless the context of the usage requires otherwise.

Any patent, publication, or other disclosure material identified herein is incorporated by reference into this specification in its entirety unless otherwise indicated, but only to the extent that the incorporated material does not conflict with existing descriptions, definitions, statements, or other disclosure material expressly set forth in this specification. As such, and to the extent necessary, the express disclosure as set forth in this specification supersedes any conflicting material incorporated by reference. Any material, or portion thereof, that is said to be incorporated by reference into this specification, but which conflicts with existing definitions, statements, or other disclosure material set forth herein, is only incorporated to the extent that no conflict arises between that incorporated material and the existing disclosure material. Applicants reserve the right to amend this specification to expressly recite any subject matter, or portion thereof, incorporated by reference herein.

One skilled in the art will recognize that the herein described components (e.g., operations), devices, objects, and the discussion accompanying them are used as examples for the sake of conceptual clarity and that various configuration modifications are contemplated. Consequently, as used herein, the specific exemplars set forth and the accompanying discussion are intended to be representative of their more general classes. In general, use of any specific exemplar is intended to be representative of its class, and the non-inclusion of specific components (e.g., operations), devices, and objects should not be taken limiting.

With respect to the appended claims, those skilled in the art will appreciate that recited operations therein may generally be performed in any order. Also, although various operational flows are presented in a sequence(s), it should be understood that the various operations may be performed in other orders than those which are illustrated, or may be performed concurrently. Examples of such alternate orderings may include overlapping, interleaved, interrupted, reordered, incremental, preparatory, supplemental, simultaneous, reverse, or other variant orderings, unless context dictates otherwise. Furthermore, terms like “responsive to,” “related to,” or other past-tense adjectives are generally not intended to exclude such variants, unless context dictates otherwise.

One skilled in the art will recognize that the herein-described components, devices, operations/actions, and objects, and the discussion accompanying them, are used as examples for the sake of conceptual clarity and that various configuration modifications are contemplated. Consequently, as used herein, the specific examples/embodiments set forth and the accompanying discussion are intended to be representative of their more general classes. In general, use of any specific exemplar is intended to be representative of its class, and the non-inclusion of specific components, devices, operations/actions, and objects should not be taken limiting. While the present disclosure provides descriptions of various specific aspects for the purpose of illustrating various aspects of the present disclosure and/or its potential applications, it is understood that variations and modifications will occur to those skilled in the art. Accordingly, the invention or inventions described herein should be understood to be at least as broad as they are claimed and not as more narrowly defined by particular illustrative aspects provided herein.

What is claimed is:

1. A conductive composition for additive manufacturing, the composition comprising:
at least 75 percent by weight of gold nanoparticles based on a total weight of the composition, the gold nanoparticles comprise an average particle size of no greater than 100 nm as measured with transmission electron microscopy; and
at least 2 percent by weight of a polar solvent based on the total weight of the composition, the polar solvent having a boiling point of at least 200° C.,
wherein the composition comprises less than 5 percent by weight of any solvent having a boiling point of less than 200° C. based on the total weight of the composition.

2. The composition of claim 1, wherein the composition comprises less than 1 percent by weight of any solvent having a boiling point of less than 200° C. based on the total weight of the composition.

3. The composition of claim 1, wherein the composition comprises less than 0.1 percent by weight of any solvent having a boiling point of less than 200° C. based on the total weight of the composition.

4. The composition of claim 1, wherein nanoparticles comprise gold bound to a polymer.

5. The composition of claim 4, wherein the polymer comprises a weight-average molecular weight in a range of 24,000 daltons to 90,000 daltons as measured according to ASTM D4001-20.

6. The composition of claim 4, wherein the polymer comprises a polyetherketone.

7. The composition of claim 4, wherein the polymer comprises polyvinylpyrrolidone, poly(vinyl alcohol), poly(ethylene glycol), poly(methacrylic acid), polymethylmethacrylate, or a combination thereof.

8. The composition of claim 1, wherein the gold nanoparticles comprise an average particle size in a range of 5 nm to 80 nm as measured by transmission electron microscopy.

9. The composition of claim 1, wherein the gold nanoparticles comprise an average particle size in a range of 20 nm to 55 nm as measured by transmission electron microscopy.

10. The composition of claim 1, wherein the gold nanoparticles comprise a mixture of spherical nanoparticles, rod-shaped nanoparticles, and triangular nanoparticles.

11. The composition of claim 1, wherein the gold nanoparticles comprise 60 percent to 80 percent by weight of spherical nanoparticles, 10 percent to 20 percent by weight of triangular nanoparticles, and 0 percent to 5 percent by weight of rod-shaped nanoparticles, all based on the total weight of the gold nanoparticles.

12. The composition of claim 1, wherein the gold nanoparticles comprise 80 percent to 95 percent by weight of spherical nanoparticles and 5 percent to 20 percent by weight of nanoparticles that are not spherical nanoparticles, all based on the total weight of the gold nanoparticles.

13. The composition of claim 1, wherein the composition comprises 76 percent to 95 percent by weight of the gold nanoparticles based on the total weight of the composition.

14. The composition of claim 1, wherein the composition comprises 80 percent to 95 percent by weight of the gold nanoparticles based on the total weight of the composition.

15. The composition of claim 1, wherein the composition comprises 81 percent to 90 percent by weight of the gold nanoparticles based on the total weight of the composition.

16. The composition of claim 1, wherein the gold nanoparticles comprise at least 90 percent gold based on the total weight of the gold nanoparticles.

17. The composition of claim 1, wherein the polar solvent comprises a polar protic solvent.

18. The composition of claim 1, wherein the polar solvent comprises triethylene glycol, glycerol, tripropylene glycol, tripropylene glycol methyl ether, diethylene glycol, tetraethylene glycol, or a combination thereof.

19. The composition of claim 1, wherein the polar solvent comprises tetraethylene glycol.

20. The composition of claim 1, further comprising a second solvent.

21. The composition of claim 1, wherein the composition comprises 10 percent to 20 percent by weight of the polar solvent based on the total weight of the composition.

22. The composition of claim 1, wherein the composition comprises 12 percent to 17 percent by weight of the polar solvent based on the total weight of the composition.

23. The composition of claim 1, wherein the composition further comprises at least 0.1 weight percent of a dispersant based on the total weight of the composition.

24. The composition of claim 23, wherein the dispersant comprises an alkylol ammonium salt of a copolymer with acidic groups, a phosphoric acid derivative, or a combination thereof.

25. The composition of claim 23, wherein the composition comprises 0.1 percent to 3 percent by weight of the dispersant based on the total weight of the composition.

26. The composition of claim 23, wherein the composition comprises 1 percent to 3 percent by weight of the dispersant based on the total weight of the composition.

27. The composition of claim 1, wherein the composition further comprises at least 0.1 weight percent of a rheological agent based on the total weight of the composition.

28. The composition of claim 27, wherein the composition comprises 1 percent to 3 percent by weight of the rheological agent based on the total weight of the composition.

29. The composition of claim 27, wherein the rheological agent comprises an ethylene oxide-based urethane, an alkali-swellable emulsion, a polyamide, polyvinyl pyrrolidone, or a combination thereof.

30. The composition of claim 1, wherein the composition comprises a dynamic viscosity of at least 100 cP as measured at 25 degrees Celsius with a rheometer with a 25 mm parallel plate measuring system and a shear rate in a range of 0.1 s⁻¹ to 100 s⁻¹.

31. The composition of claim 1, wherein the composition reduces in viscosity responsive to a shear force.

32. A conductive composition for additive manufacturing, the composition comprising:
80 percent to 95 percent by weight of gold nanoparticles based on a total weight of the composition, the gold nanoparticles comprise an average particle size in a range of 20 nm to 55 nm as measured with transmission electron microscopy, wherein the gold nanoparticles comprise gold bound to a polymer having a molecular weight in a range of 24,000 daltons to 90,000 daltons;
2 percent to 19 percent by weight of a solvent comprising tetraethylene glycol;
1 percent to 3 percent by weight of a polymeric dispersant based on the total weight of the composition; and
1 percent to 3 percent by weight of a rheological agent based on the total weight of the composition,
wherein the composition comprises less than 1 percent by weight of any solvent having a boiling point of less than 200° C. based on the total weight of the composition.

33. An additive manufacturing method, the method comprising extruding the composition of claim 1 from a nozzle of an additive manufacturing system, thereby producing an electrically conductive feature.

34. The method of claim 33, wherein the electrically conductive feature comprises a line width of no greater than 10 μm.

35. The method of claim 33, wherein the electrically conductive feature comprises an aspect ratio of at least 0.2.

36. The method of claim 33, wherein extruding the composition from the nozzle of the additive manufacturing system is performed at a line speed 0.1 mm/s to 2 mm/s.

37. The method of claim 33, further comprising sintering the electrically conductive feature, thereby forming an electrically conductive trace.

38. An electrically conductive trace formed by sintering the composition of claim 1.

39. An electronic article comprising the electrically conductive trace of claim 38.
